(19) United States
(12) Patent Application Publication
(10) Pub. No.: US 2017/0205771 A1
(43) Pub. Date: Jul. 20, 2017

(54) WATCH AND METHOD FOR MANUFACTURING THE SAME

(71) Applicant: EVERDISPLAY OPTRONICS (SHANGHAI) LIMITED, SHANGHAI (CN)

(72) Inventors: Hsin Chih LIN, SHANGHAI (CN); Chungche TSOU, SHANGHAI (CN); PingI SHIH, SHANGHAI (CN)

(73) Assignee: EVERDISPLAY OPTRONICS (SHANGHAI) LIMITED, SHANGHAI (CN)

(21) Appl. No.: 15/245,296

(22) Filed: Aug. 24, 2016

(30) Foreign Application Priority Data
Jan. 18, 2016 (CN) 201610031708.2

(51) Int. Cl. G04C 17/00; H01L 27/32; H01L 51/56; G04G 9/00

(52) U.S. Cl. CPC G04C 17/0091; G04G 9/0064; H01L 27/3225; H01L 27/3244; H01L 51/56

(57) ABSTRACT

The present disclosure relates to a watch and a method for manufacturing the same. The watch includes: a movement component; a display panel including: a first substrate disposed over the watch movement; a through hole passing through the display panel; a display element disposed on the first substrate and surrounding the through hole; and a package unit for packaging the display element and including at least a first package portion disposed on the first substrate, surrounding the through hole and located between the through hole and the display element so as to prevent external water or oxygen contacting the display element; a spindle disposed in the through hole and connected with the watch movement; and a pointer portion disposed over the display panel and connected with the spindle.

### CROSS-REFERENCE TO RELATED APPLICATIONS

This application claims priority to Chinese Patent Application No. 201610031708.2, filed Jan. 18, 2016, the entire contents of which are incorporated herein by reference.

### TECHNICAL FIELD

The present disclosure generally relates to watch technologies, and more particularly to, a watch having a display panel and a method for manufacturing the same.

### BACKGROUND

Because of advantages such as wide color gamut, high contrast, lightness, AMOLEDs (Active Matrix Organic Light Emitting Diode) have gradually replaced LCD (Liquid Crystal Display) panels in the flat panel display field and been widely applied in mobile phones. With development of mobile technologies, digital products have become functional, small-sized and portable. Wearable products, particularly smart watches, have emerged on the market. As a new product rising in recent years, smart watches have attracted more and more attention. Smart watches usually have fashion forms and multifaceted functions and are conveniently portable, and thus they seem able to compete with mobile phones. In order to improve display performance and to realize miniaturization, AMOLED display panels are used in smart watches, for example, Apple Watch, Huawei Watch, and the like.

However, the emergence of smart watches does not shake the position of conventional mechanical analogue watches in the watch market. Conventional mechanical watches are still preferred by customers due to their fashion shapes, high grade, fineness and mature processes. The emergence of smart watches can give new perspectives on conventional mechanical analogue watches, and manufactures and developers also want to add intelligence functions onto the mechanical watches to upgrade functions while maintaining the old advantages of the mechanical watches. In order to realize intelligent functions, in addition to elements like intelligent sensors which are currently mounted in smart watches, display panels are also needed to deliver various information to wearers. Although a part of existing mechanical watches has a display panel, the display panel can only display simple numbers or patterns, and thereby cannot meet the requirement of displaying variety of information as smart watches do. In order to realize wide color gamut, high contrast, lightness and diversified display, AMOLEDs are a good choice for display panels.

The main difference between providing an AMOLED display panel in a mechanical analogue watch and providing an AMOLED display in a smart watch is that a through hole needs to be provided in the center of the display panel to enable the spindle of the watch to pass through, so that pointer members can be mounted on the spindle of the watch to realize various functions of the mechanical watches. After providing the through hole in the center of the display panel, the external oxygen and moisture (or water) are intended to invade into the display panel, thereby influencing the performance and service life of the display panel. Thus, providing the through hole in the center of an AMOLED display panel brings challenges to manufacturing technologies of AMOLEDs, such as evaporation and packaging.

At present, there are generally two types of technologies for packaging AMOLED display panels. One type of technology is to use an ultraviolet adhesive or frit to adhere a substrate with a cover plate so as to realize the encapsulation effect. The other type is to deposit water-blocking thin film layers on a substrate using thin film encapsulation processes to block water and oxygen. However, both the above two types of technologies need to package the display panel, and thus invading of external water and oxygen into the display panel via the through hole provided in the center of the display panel is unavoidable. As a result, the external water and oxygen may contact the display panel, influence the display performance of the display panel and may even make it ineffective.

### SUMMARY

Aiming at the shortcomings in conventional technologies, embodiments of the present disclosure provide a watch and a method for manufacturing the same.

An aspect of embodiments of the present disclosure provide a watch, including:

a movement component;

a display panel including:

a first substrate disposed over the movement component;

a through hole passing through the display panel;

a display element disposed on the first substrate and surrounding the through hole; and

a package unit for packaging the display element on the first substrate, wherein the package unit includes a first package portion disposed on the first substrate, surrounding the through hole and located between the through hole and the display element so as to prevent external water or oxygen contacting the display element;

a spindle disposed in the through hole and connected with the movement component; and

a pointer portion disposed over the display panel and connected with the spindle.

According to an exemplary embodiment, the display panel further includes a second substrate disposed over the display panel, and the first package portion is disposed between the first substrate and the second substrate; the package unit further includes a second package portion which surrounds the display element and is disposed between the first substrate and the second substrate.

According to an exemplary embodiment, the first package portion and the second package portion are formed by an ultraviolet adhesive or frit.

According to an exemplary embodiment, the package unit further includes a third package portion which is disposed on the first substrate, surrounds and covers the display element and is connected with the first package portion so as to enclose the display element along with the first package portion.

According to an exemplary embodiment, the first package portion and the third package portion both include at least one inorganic layer and at least one organic layer which are alternately stacked on the first substrate.

According to an exemplary embodiment, the at least one organic thin film layer is formed by acrylic resin, and the at least one inorganic thin film layer is formed by silicon nitride, aluminum oxide or titanium dioxide.

According to an exemplary embodiment, the through hole has a diameter of 1 to 3 mm.

According to an exemplary embodiment, the display element is an active matrix organic light emitting diode display device which includes:

a thin film transistor array disposed on the first substrate;

an anode disposed on and electrically connected with the thin film transistor array;

a light-emitting layer disposed on the anode; and

a cathode disposed over the light-emitting layer.

Another aspect of embodiments of the present disclosure provides a method for manufacturing a watch, including:

providing a first substrate, and forming a mask portion on a region on the first substrate;

forming a display element on the first substrate and the mask portion;

removing the mask portion and the display element on the mask portion so that the display element on the first substrate has a hollow portion;

packaging the display element to form a display panel which includes at least a first package portion formed on the first substrate and surrounding at least the hollow portion;

providing a through hole passing through the display panel in a region of the display panel corresponding to the hollow portion, wherein the first package portion surrounds the through hole;

connecting a spindle to a movement component by passing the spindle through the through hole of the display panel and mounting a pointer portion on the spindle, wherein the movement component and the pointer portion are placed at upper and lower sides of the display panel.

According to an exemplary embodiment, the formation of the mask portion on the first substrate includes:

forming a photoresist layer on the first substrate, and forming the mask portion by exposure and development.

According to an exemplary embodiment, the removing of the mask portion and the display element on the mask portion includes:

immersing the first substrate, the mask portion and the display element into a film-removing solvent which only reacts with the mask portion but does not react with the display element.

According to an exemplary embodiment, the packaging of the display element includes:

coating a package adhesive on the first substrate, wherein the coated package adhesive surrounds the hollow portion and the display element;

covering a second substrate over the first substrate; and

curing the package adhesive to form a first package portion and a second package portion which adhere the first substrate with the second substrate, wherein the first package portion surrounds the hollow portion, and the second package portion surrounds the display element.

According to an exemplary embodiment, the package adhesive is an ultraviolet adhesive which is capable of adhering the firs substrate with the second substrate after being cured by irradiation of ultraviolet light.

According to an exemplary embodiment, the package adhesive is a frit which is capable of adhering the firs substrate with the second substrate after being cured by laser sintering.

According to an exemplary embodiment, the packaging of the display element includes:

alternately depositing at least one inorganic layer and at least one organic layer on the first substrate until the display element is covered, wherein the at least one inorganic layer and the at least one organic layer form a first package layer and a third package layer, the first package layer is formed in the hollow portion, and the third package surrounds and covers the display element.

In the watch provided by embodiments of the present disclosure, a first package portion is provided between a display element and a through hole for enabling a spindle of the watch to pass through and the first package portion surrounds the through hole. Thus, the watch can prevent external water and oxygen from invading into the display panel via the through hole and thereby contacting the display element. Consequently, the normal display performance of the display panel can be guaranteed and the service life of the display panel can be lengthened.

In addition, in the method for manufacturing the watch provided by the present disclosure, photolithography and evaporation technologies are combined. Specifically, a mask portion is formed on the first substrate by photolithography before depositing the display element, and then the display element can be formed on both the first substrate and the mask portion at the same time during the deposition of the display element. Thus, a hollow portion can be formed in the display element on the first substrate while removing the mask portion. As a result, the first package portion surrounding the through hole can be formed in the hollow portion during the packaging procedure for preventing external water and oxygen from invading into the display panel via the through hole and contacting the display element.

In existing manufacturing method, a mask region is added to a position on the first substrate where a through hole is to be provided by using a mask during the evaporation procedure (specifically, in order to add the mask region, a blocking portion needs to be added into the mask, while the blocking portion needs to be supported by supporting members which will block the deposition of the display element during the evaporation, thereby reducing effective area of the display element on the first substrate). By comparison, the manufacturing method provided by the present disclosure can enable the display panel to normally display images and video except the center portion of the display panel. Consequently, the display area of the display panel can be increased, and the use experience of wearers can be improved.

### BRIEF DESCRIPTION OF THE DRAWINGS

Other features, objectives and advantages of the present disclosure will become clearer from the following detailed description regarding non-restrictive embodiments with reference to drawings.

FIG. 1 is a cross-sectional view of a watch according to an embodiment of the present disclosure.

FIG. 2 is a top view of the watch in FIG. 1.

FIG. 3 is a flowchart showing a method for manufacturing the watch in FIG. 1.

FIG. 4 is a schematic diagram showing a structure of the watch in FIG. 1 after a mask portion is formed by forming a negative photoresist on a first substrate and exposing and developing the negative photoresist.

FIG. 5 is a schematic diagram showing a structure of the watch in FIG. 1 after two positive photoresist layers are formed on the first substrate and the upper positive photoresist is exposed and developed.

FIG. 6 is a schematic diagram showing a structure after the lower positive photoresist layer in FIG. 5 is etched to form a mask portion.

FIG. 7 is a schematic diagram showing a structure after a display element in the watch in FIG. 1 is formed on the first substrate and the mask portion.

FIG. 8 is schematic diagram showing a structure after the first substrate is immersed into a film-removing solvent.

FIG. 9 is a schematic diagram showing a structure after the mask portion and the display element on the mask portion are removed.

FIG. 10 is a schematic diagram showing a structure after a package adhesive is coated on the first substrate.

FIG. 11 is a schematic diagram showing a structure after the first substrate is covered and the package adhesive is cured.

FIG. 12 is a schematic diagram showing a structure after a through hole is provided in the display panel.

FIG. 13 is a schematic diagram showing a structure after the display panel is adhered with a circuit board.

FIG. 14 is a cross-sectional view of a watch according to an exemplary embodiment.

FIG. 15 is a schematic diagram showing a structure after a display panel in the watch of FIG. 14 is packaged.

FIG. 16 is a schematic diagram showing a structure after a through hole is provided in the display panel of the watch in FIG. 14.

### DETAILED DESCRIPTION

Technical solutions of the present disclosure will be described in detail with reference to drawings and exemplary embodiments.

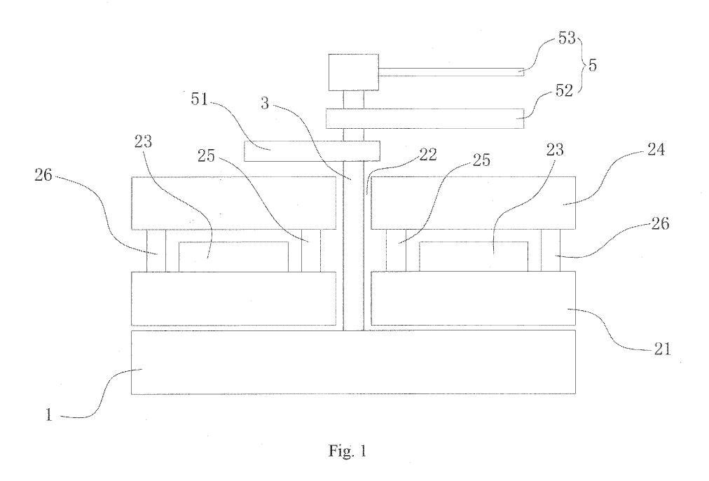

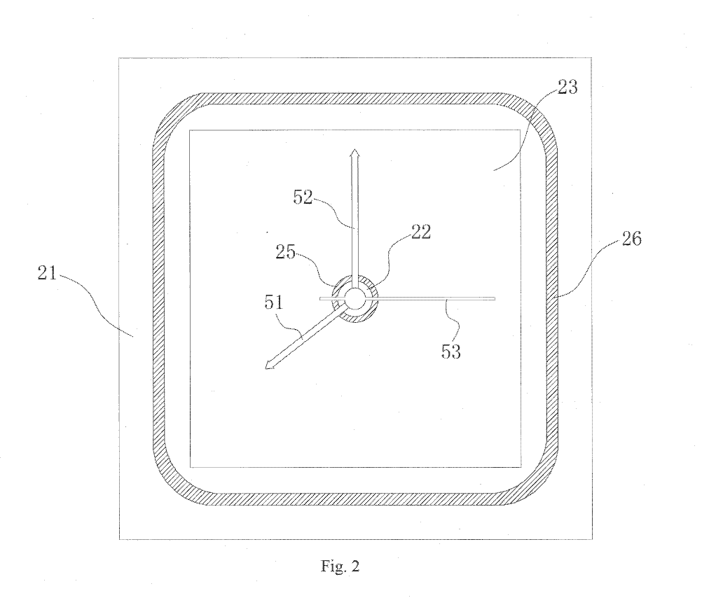

FIGS. 1 and 2 are cross-sectional view and top view of a watch according to an embodiment of the present disclosure, respectively. In an exemplary embodiment of the present disclosure, the watch includes a movement component 1, a display panel, a spindle 3 and a pointer portion 5. It should be noted that in order to clearly show a first package layer and a second package layer inside the display panel, a second substrate of the display panel is omitted in FIG. 2.

The display panel is disposed over the movement component 1. Specifically, in the embodiment as shown in FIGS. 1 and 2, the display panel includes a first substrate 21, a through hole 22, a display element 23, a second substrate 24 and a package unit for packaging the display element 23.

Specifically, the first substrate 21 is disposed over the movement component 1. The first substrate 21 is adhered to a flexible circuit board (not shown) which includes IC driving circuits thereon for controlling the display panel.

In an exemplary embodiment of the present disclosure, the through hole 22 is disposed in the center of the display panel and passes through the display panel. In the embodiment as shown in FIG. 1, the through hole goes through the first substrate 21 and the second substrate 24 along a direction perpendicular to the firs substrate 21. The through hole 22 is provided to enable the spindle 3 of the watch to pass through, and thus has a size adapt to that of the spindle 3. Optionally, in the top view in FIG. 2, the diameter of the through hole may be 1 to 3 mm.

The display element 23 surrounds the through hole 22 and is disposed on the first substrate 21. In an exemplary embodiment of the present disclosure, the display device 23 may be an AMOLED display device, which may have a structure similar to that of a conventional AMOLED display element. For example, the display element 23 may include a thin film transistor array, an anode, a light-emitting layer and a cathode. The thin film transistor array is disposed on the first substrate 21. The anode is disposed on and electrically connected with the thin film transistor array. The light-emitting layer is disposed on the anode layer. The cathode is disposed over the light-emitting layer. Detailed descriptions are omitted here.

In the embodiment as shown in FIGS. 1 and 2, the display panel is packaged by covering the second substrate 24 over the first substrate 21 and then adhering the two substrates using a package adhesive. Specifically, the second substrate 24 is disposed over the display element 23. Optionally, the second substrate 24 is spaced from the display device 23. The package unit includes a first package portion 25 and a second package portion 26.

The first package portion 25 is disposed on the first substrate 21 around the through hole 22, and is located between the first substrate 21 and the second substrate 24. Specifically, as shown in FIG. 1, the first package portion 25 is located between the through hole 22 and the display element 23 for blocking external water and oxygen from invading into the display panel via the through hole 22 to contact the display element 23. In the embodiment, optionally, the first package portion 25 is formed by an ultraviolet adhesive or fit. When the first package portion 25 is formed by an ultraviolet adhesive, the ultraviolet adhesive is cured by irradiation of ultraviolet light to be adhered between the first substrate 21 and the second substrate 24. When the first package portion 25 is formed by a frit, the frit is adhered between the first substrate 21 and the second substrate 24 by laser sintering.

The second package portion 26 surrounds the display element 23, and is disposed between the first substrate 21 and the second substrate 24. As shown in FIG. 1, the second package portion 26 surrounds the outer peripheral of the display element 23. Like the first package portion 25, optionally, the second package portion 26 is formed by an ultraviolet adhesive or frit. When the second package portion 26 is formed by an ultraviolet adhesive, the ultraviolet adhesive is cured by irradiation of ultraviolet light to be adhered between the first substrate 21 and the second substrate 24. When the second package portion 26 is formed by a frit, the frit is adhered between the first substrate 21 and the second substrate 24 by laser sintering.

After packaging, the display element 23 is located in an enclosed space formed by the first substrate 21, the second substrate 24, the first package portion 25 and the second package portion 26. The first package portion 25 can effectively prevent external water or oxygen from invading into the display panel via the through hole 22 after the through hole 22 is provided in the display panel, which may influence the display performance of the display element 23 and may even make it ineffective.

The spindle 3 is connected with the movement component 1 by passing through the through hole 22 of the display panel.

The pointer portion 5 is disposed over the display panel and connected with the spindle 3. Specifically, one end of the spindle 3 is connected with the movement component 1, and the other end of the spindle 3 is connected with the pointer portion 5, and thus the movement component 1 can drive the pointer portion 5 by the spindle 3. As shown in FIG. 2, the pointer portion 5 may include an hour pointer (hour hand) 51, a minute pointer (minute hand) 52 and a second pointer (second hand) 53. As shown in FIG. 1, the pointer portion 5 is disposed over the second substrate 24.

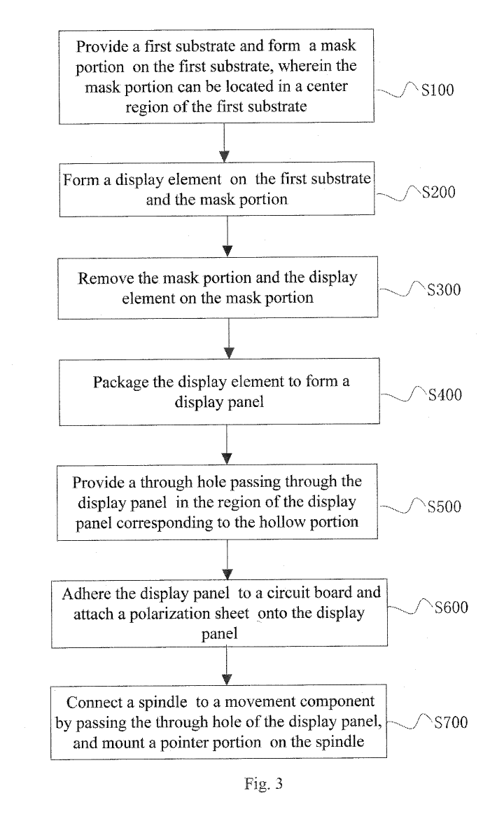

FIGS. 3 to 13 are flowchart showing a method for manufacturing a watch according to an embodiment of the present disclosure and schematic diagrams showing the structures after respective steps are finished during the manufacturing procedure. Specifically, the present disclosure further provides a method for manufacturing the watch as shown in FIGS. 1 and 2. The method for manufacturing the watch can include the following steps.

In step S100, a first substrate is provided, and a mask portion is formed on the first substrate. Optionally, the mask portion can be located in the center region of the first substrate. The mask portion can be formed by forming a photoresist layer on the first substrate and then performing exposure and development.

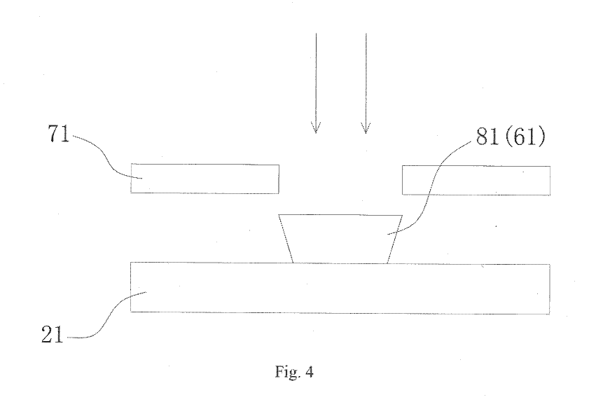

Referring to FIG. 4, in an exemplary embodiment, the mask portion can be formed as follows. A negative photoresist layer 61 is coated on the first substrate 21, and then the negative photoresist 61 is exposed and developed. During the exposure and development, the negative photoresist 61 is blocked (shielded) using a mask 71. The mask 71 has a size adapt to the size of the negative photoresist 61 with an opening at the center region. The region of the negative photoresist 61 corresponding to the opening does not dissolve in the developing liquid after light irradiation, but other portions all dissolve into the developing liquid. After removing, the portion not dissolving into the developing liquid forms a mask portion. As shown in FIG. 4, because of the shadow effect during the exposure, the cross section of the resulted mask portion 81 has an inverted trapezoidal shape, i.e., the side contacting the first substrate 21 is smaller than the side away from the first substrate 21. Thus, the formation of display element at the side wall of the mask portion 81 can be avoided during subsequent procedure for forming the display element.

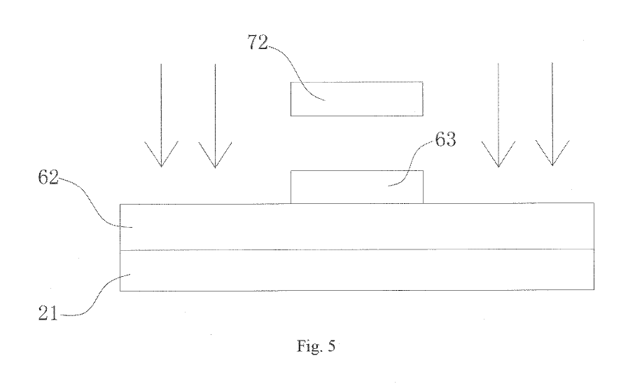

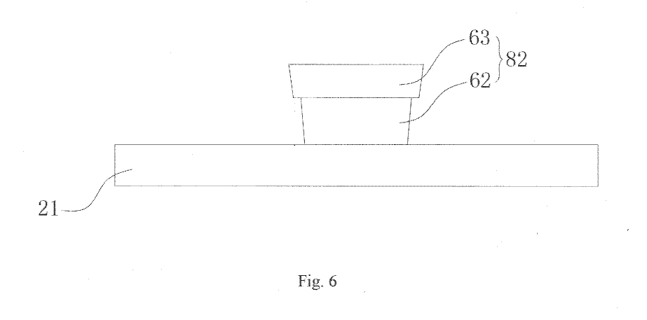

Further, referring to FIGS. 5 and 6, in another exemplary embodiment of the present disclosure, the mask portion may be formed as follows. Two layers of positive photoresists 62 and 63 are coated on the first substrate 21. The positive photoresist 63 on the positive photoresist 62 is exposed and developed. During the exposure and development, a mask 72 which has a substantially circle shape, is used to block the center region of the positive photoresist 63. The portion of the positive photoresist 63 which is blocked by the mask 72 does not dissolve into the developing liquid, and other portions all dissolve into the developing liquid. After removing, the positive photoresist 62 is etched to form another mask portion 82. As shown in FIG. 6, the portion of the positive photoresist 63 which does not dissolve into the developing liquid and the left portion of the positive photoresist 62 after etching form the mask portion 82. The mask portion 82 has an inverted trapezoidal shape, i.e., the size of the positive photoresist 63 is greater than the size of the positive photoresist 62. Thus, the formation of the display element at the side wall of the mask portion 82 can be avoided during the subsequent procedure for forming the display element.

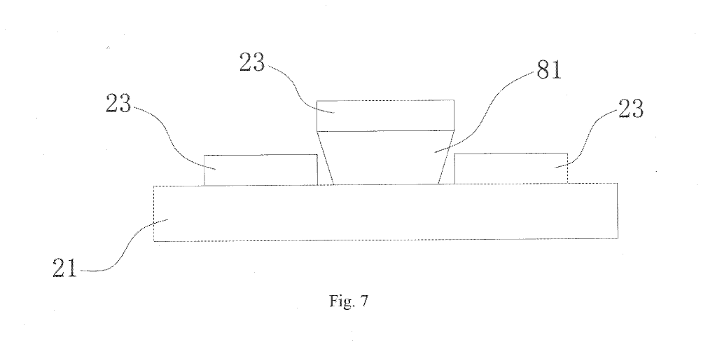

In step S200, a display element is formed on the first substrate and the mask portion. Specifically, as shown in FIG. 7, the display element 23 is formed on the first substrate 21 as shown in FIG. 4 by film plating technologies such as deposition. Due to the existence of the mask portion 81, there is no display element in the region on the first substrate 21 where the mask portion 81 is located, and the display element corresponding to the region is formed on the mask portion 81.

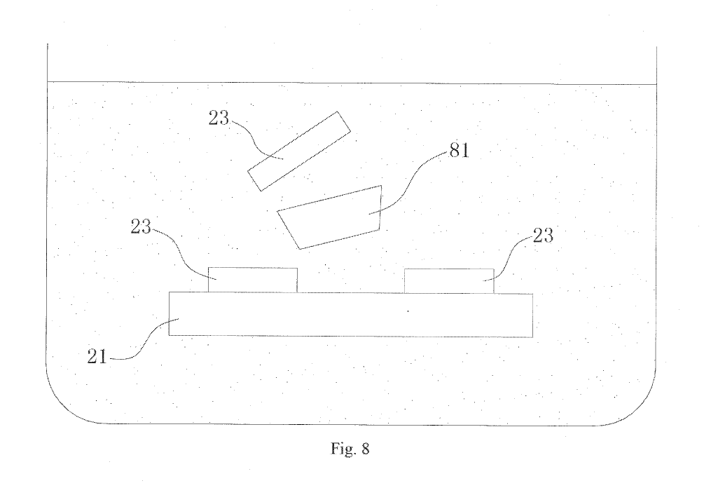

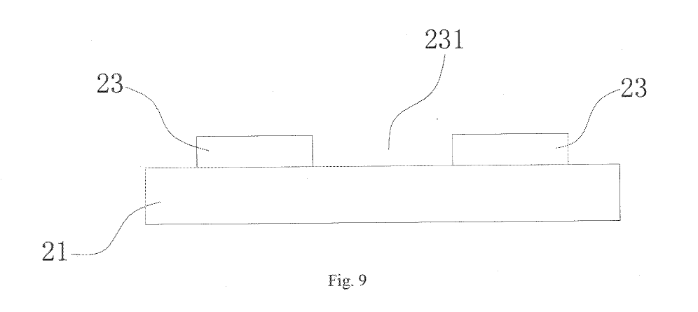

In step S300, the mask portion and the display element on the mask portion are removed to make the display element on the first substrate have a hollow portion. Referring to FIGS. 8 and 9, specifically, the first substrate 21, the mask portion 81 and the display element 23 as shown in FIG. 7 are immersed into a film-removing solvent which only reacts with the mask portion (or mask layer) but does not react with the display element, for example, the film-removing solvent may be a film-removing solvent containing fluorides. As shown in FIG. 8, because the mask portion 81 is removed by reacting with the film-removing solvent, the display element 23 on the mask portion 81 can be removed along with the mask portion 81. It should be noted that, in exemplary embodiments of the present disclosure, after step S300 is completed, the remaining film-removing solvent on the first substrate 21 may be removed. The method for removing the film-removing solvent can include placing the first substrate 21 into an oven to bake the first substrate 21. As shown in FIG. 9, after the mask portion 81 is removed, the display element 23 on the first substrate 21 has a hollow portion 231.

In step S400, the display element is packaged to form a display panel. The display panel at least includes a first package portion which is formed on the first substrate and surrounds edges of the hollow portion. Specifically, the packaging of the display element can include the following sub-steps.

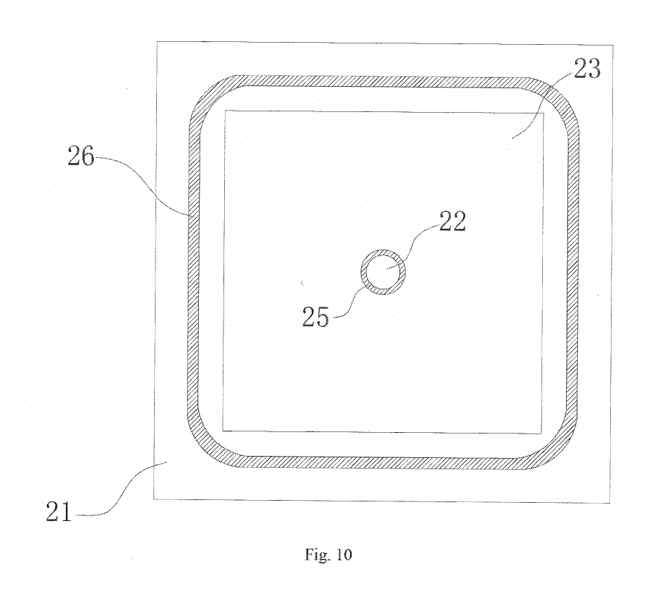

As shown in FIG. 10, a package adhesive is coated on the first substrate 21. The package adhesive is coated around the hollowing portion 231 and the display element 23.

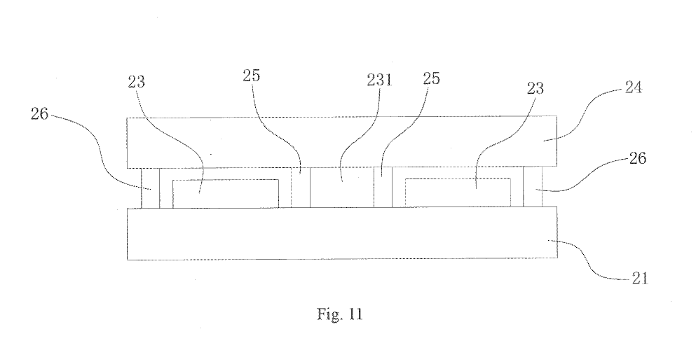

Then, the second substrate 24 is covered over the first substrate 21, the package adhesive is cured to form the first package portion 25 and the second package portion 26. The first package portion 25 is formed by curing the package adhesive around the hollow portion 231, and the second package portion 26 is formed by curing the package adhesive around the display element 23. In the embodiment, the first package portion 25 and the second package portion 26 can be formed by an ultraviolet adhesive or frit. When the first package portion 25 and the second package portion 26 are formed by an ultraviolet adhesive, the ultraviolet adhesive is cured by irradiation of ultraviolet light to be adhered between the first substrate 21 and the second substrate 24. When the first package portion 25 and the second package portion 26 are formed by a frit, the frit is adhered between the first substrate 21 and the second substrate 24 by laser sintering. Repeated descriptions are omitted here. The display panel as shown in FIG. 11 can be formed after packaging.

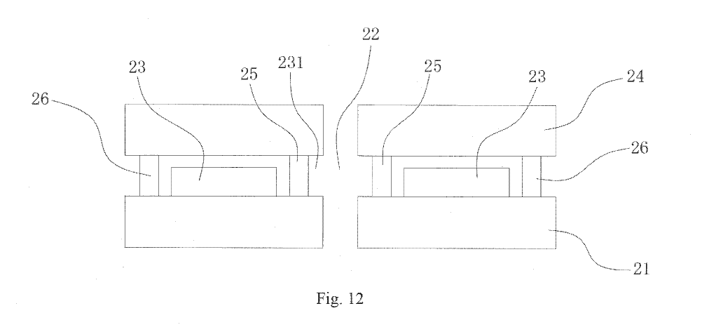

In step S500, a through hole passing through the display panel is provided in the region of the display panel corresponding to the hollow portion. Specifically, a through hole 22 is provided in the display panel as shown in FIG. 11. The through hole 22 goes through the display panel along a direction perpendicular to the first substrate 21 and the second substrate 22, and corresponds to the hollow portion 231 of the display element 23. The through hole 22 can be formed by mechanical drilling or laser drilling. As shown in FIG. 12, after the through hole 23 is formed, the first package portion 25 surrounds the through hole 22 and is located between the through hole 22 and the display element 23.

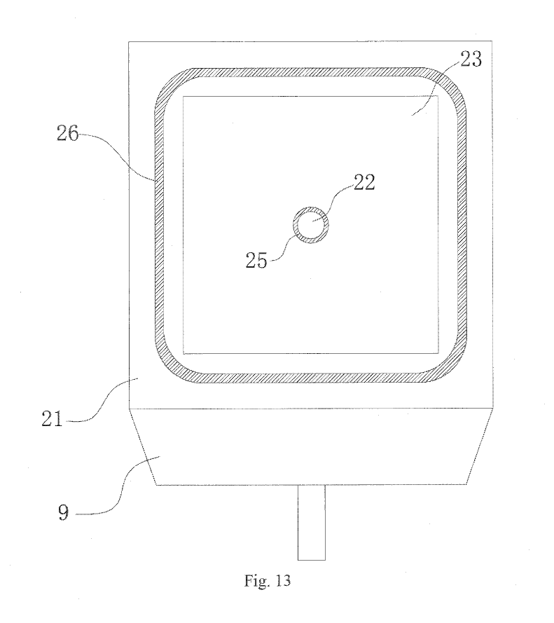

In step S600, the display panel is adhered to a circuit board and a polarization sheet is attached onto the display panel. Specifically, as shown in FIG. 13, the first substrate 21 of the display panel as shown in FIG. 12 is adhered to a circuit board 9. The display panel is electrically connected with the circuit board 9, and IC driving circuits and the like on the circuit board 9 can control the display of the display panel. After the adhering is completed, an optical polarization sheet can be attached onto the light-out surface of the display panel. In order to clearly show the structures and positions of the first package portion and the second package portion, the second substrate and the optical polarization sheet attached onto the second substrate are omitted in FIG. 13.

In step S700, a spindle is connected to a movement component by passing the through hole of the display panel, and a pointer portion is mounted on the spindle. The movement component and the pointer portion are placed at both sides of the display panel, and then the watch as shown in FIGS. 1 and 2 are formed.

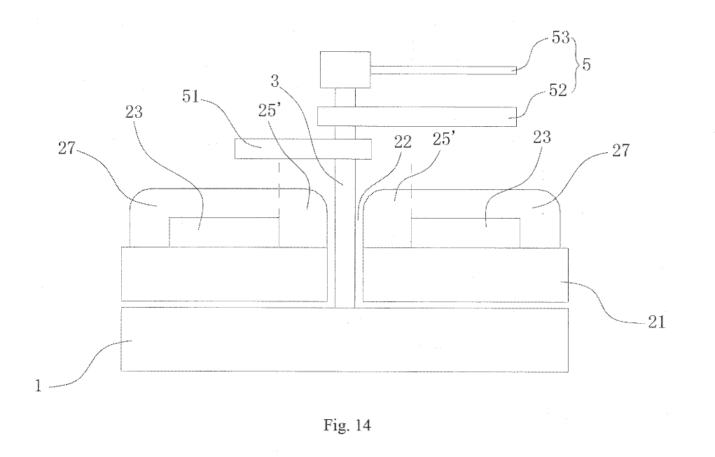

FIG. 14 is a cross-sectional view of a watch according to another embodiment of the present disclosure. The difference between the watch in FIG. 14 and the watch in FIGS. 1 and 2 is that the display panel in this embodiment is packaged using thin film package technologies. Specifically, as shown in FIG. 14, the package unit includes a first package portion 25′ and a third package portion 27. As with the above embodiment, the first package portion 25′ is disposed on the first substrate 21 around the through hole 22.

The third package portion 27 is disposed on the first substrate 21, surrounds and covers the display element 23, and is connected with the first package portion 25′ to enclose the display element 23 with the first package portion 25′. It should be noted that the first package portion 25′ and the third package portion 27 can be formed on the first substrate 21 by film plating technologies such as deposition, and thus the first package portion 25′ and the third package portion 27 can be taken as an entirety. Specifically, the first package portion 25′ and the third package portion 27 both include at least one inorganic thin film layer and at least one organic thin film (not shown) which are alternately stacked and deposited on the first substrate 21. The organic thin film is optionally formed by acrylic resin, and the at least one inorganic thin film layer is formed by silicon nitride, aluminum oxide or titanium dioxide.

Further, in an embodiment of the present disclosure, the display panel can further include a protection layer (not shown) which may be disposed on the third package portion 27 for protecting the surface of the display panel, and detailed description is omitted here.

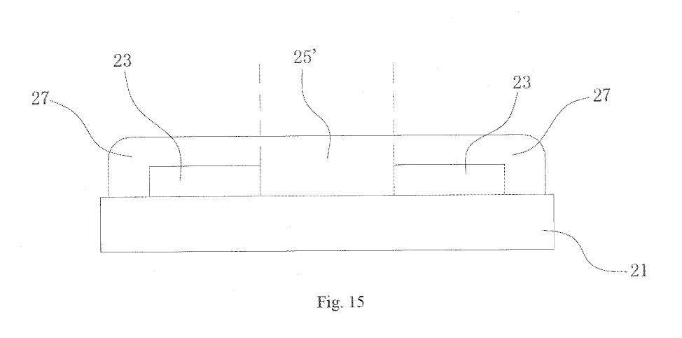

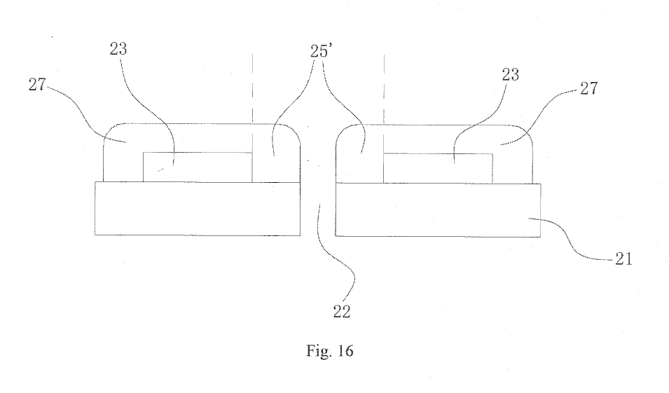

FIG. 15 is a schematic diagram showing the structure after the display panel is packaged. FIG. 16 is a schematic diagram showing the structure after the through hole is provided in the display panel. As shown in FIGS. 15 and 16, the package step of the display panel in the embodiment is different from the embodiment described in connection with FIGS. 1 and 2. Specifically, the step for packaging the display element can include the following steps.

At least one inorganic thin film layer and at least one organic thin film layer are alternately deposited on the first substrate 21 until the display element 23 is covered. The at least one inorganic thin film layer and at least one organic thin film layer form the first package layer 25′ and the third package layer 27, the first package layer 25′ is formed in the hollow portion 231, and the third package 27 surrounds and covers the display element 23. Referring to FIG. 15, the portion between two dotted lines in this figure is the first package portion 25′.

As shown in FIG. 16, during the procedure of forming the through hole 22 in the display panel in FIG. 15, because the through hole 22 corresponds to the hollow portion of the display element 23, and the first package layer 25′ is disposed in the hollow portion 231 in this embodiment, the through hole 22 goes through the first package layer 25′ and the first substrate 21. Then, after formation of the through hole 22, the first package layer 25′ surrounds the through hole 22.

Further, as with the above embodiment described in connection with FIGS. 1 and 2, a spindle is connected to the movement component by passing through the through hole in the display panel as shown in FIG. 16, the pointer portion is mounted on the spindle, and then the watch as shown in FIG. 14 is formed.

In view of the above, in the watch provided by embodiments of the present disclosure, a first package portion is provided between a display element and a through hole for enabling a spindle of the watch to pass through and the first package portion surrounds the through hole. Thus, the watch can prevent external water and oxygen from invading into the display panel via the through hole and thereby contacting the display element. Consequently, the normal display performance of the display panel can be guaranteed and the service life of the display panel can be lengthened.

In addition, in the method for manufacturing the watch provided by the present disclosure, photolithography and evaporation technologies are combined. Specifically, a mask portion is formed on the first substrate by photolithography before depositing the display element, and then the display element can be formed on both the first substrate and the mask portion at the same time during the deposition of the display element. Thus, a hollow portion can be formed in the display element on the first substrate while removing the mask portion. As a result, the first package portion surrounding the through hole can be formed in the hollow portion during the packaging procedure for preventing external water and oxygen from invading into the display panel via the through hole and contacting the display element.

In existing manufacturing method, a mask region is added to a position on the first substrate where a through hole is to be provided by using a mask during the evaporation procedure (specifically, in order to add the mask region, a blocking portion needs to be added into the mask, while the blocking portion needs to be supported by supporting members which will block the deposition of the display element during the evaporation, thereby reducing effective area of the display element on the first substrate). By comparison, the manufacturing method provided by the present disclosure can enable the display panel to normally display images and video except the center portion of the display panel. Consequently, the display area of the display panel can be increased, and the use experience of wearers can be improved.

While the present disclosure is described with reference to some exemplary embodiments, these exemplary embodiments are not for limiting the present disclosure. One of ordinary skill in this art can make various changes, amendments, substitutions, and modifications without departing from the spirit and scope of the present disclosure. Thus, the protection scope of the present disclosure should be defined by appended claims.

What is claimed is:

1. A watch, comprising:
a movement component;
a display panel comprising:
a first substrate disposed over the movement component;
a through hole passing through the display panel;
a display element disposed on the first substrate and surrounding the through hole; and
a package unit for packaging the display element on the first substrate, wherein the package unit comprises a first package portion disposed on the first substrate, surrounding the through hole and located between the through hole and the display element so as to prevent external water or oxygen contacting the display element;
a spindle disposed in the through hole and connected with the movement component; and
a pointer portion disposed over the display panel and connected with the spindle.

2. The watch according to claim 1, wherein the display panel further comprises a second substrate disposed over the display panel, and the first package portion is disposed between the first substrate and the second substrate;
wherein the package unit further comprises a second package portion which surrounds the display element and is disposed between the first substrate and the second substrate.

3. The watch according to claim 2, wherein the first package portion and the second package portion are formed by an ultraviolet adhesive or frit.

4. The watch according to claim 1, wherein the package unit further comprises a third package portion which is disposed on the first substrate, surrounds and covers the display element and is connected with the first package portion so as to enclose the display element along with the first package portion.

5. The watch according to claim 4, wherein the first package portion and the third package portion both comprise at least one inorganic layer and at least one organic layer which are alternately stacked on the first substrate.

6. The watch according to claim 5, wherein the at least one organic layer is formed by acrylic resin, and the at least one inorganic layer is formed by silicon nitride, aluminum oxide or titanium dioxide.

7. The watch according to claim 1, wherein the through hole has a diameter of 1 to 3 mm.

8. The watch according to claim 2, wherein the through hole has a diameter of 1 to 3 mm.

9. The watch according to claim 3, wherein the through hole has a diameter of 1 to 3 mm.

10. The watch according to claim 1, wherein the display element is an active matrix organic light emitting diode display device which comprises:
a thin film transistor array disposed on the first substrate;
an anode disposed on and electrically connected with the thin film transistor array;
a light-emitting layer disposed on the anode; and
a cathode disposed over the light-emitting layer.

11. The watch according to claim 2, wherein the display element is an active matrix organic light emitting diode display device which comprises:
a thin film transistor array disposed on the first substrate;
an anode disposed on and electrically connected with the thin film transistor array;
a light-emitting layer disposed on the anode; and
a cathode disposed over the light-emitting layer.

12. The watch according to claim 3, wherein the display element is an active matrix organic light emitting diode display device which comprises:
a thin film transistor array disposed on the first substrate;
an anode disposed on and electrically connected with the thin film transistor array;
a light-emitting layer disposed on the anode; and
a cathode disposed over the light-emitting layer.

13. The watch according to claim 4, wherein the display element is an active matrix organic light emitting diode display device which comprises:
a thin film transistor array disposed on the first substrate;
an anode disposed on and electrically connected with the thin film transistor array;
a light-emitting layer disposed on the anode; and
a cathode disposed over the light-emitting layer.

14. A method for manufacturing a watch, comprising:
providing a first substrate, and forming a mask portion on a region on the first substrate;
forming a display element on the first substrate and the mask portion;
removing the mask portion and the display element on the mask portion so that the display element on the first substrate has a hollow portion;
packaging the display element to form a display panel which comprises at least a first package portion formed on the first substrate and surrounding at least the hollow portion;
providing a through hole passing through the display panel in a region of the display panel corresponding to the hollow portion, wherein the first package portion surrounds the through hole;
connecting a spindle to a movement component by passing the spindle through the through hole of the display panel and mounting a pointer portion on the spindle, wherein the movement component and the pointer portion are placed at upper and lower sides of the display panel.

15. The method according to claim 14, wherein the formation of the mask portion on the first substrate comprises:
forming a photoresist layer on the first substrate, and forming the mask portion by exposure and development.

16. The method according to claim 14, wherein the removing of the mask portion and the display element on the mask portion comprises:
immersing the first substrate, the mask portion and the display element into a film-removing solvent which only reacts with the mask portion but does not react with the display element.

17. The method according to claim 14, wherein the packaging of the display element comprises:
coating a package adhesive on the first substrate, wherein the coated package adhesive surrounds the hollow portion and the display element;
covering a second substrate over the first substrate; and
curing the package adhesive to form a first package portion and a second package portion which adhere the first substrate with the second substrate, wherein the first package portion surrounds the hollow portion, and the second package portion surrounds the display element.

18. The method according to claim 17, wherein the package adhesive is an ultraviolet adhesive which is capable of adhering the firs substrate with the second substrate after being cured by irradiation of ultraviolet light.

19. The method according to claim 17, wherein the package adhesive is a frit which is capable of adhering the firs substrate with the second substrate after being cured by laser sintering.

20. The method according to claim 14, wherein the packaging of the display element comprises:
alternately depositing at least one inorganic layer and at least one organic layer on the first substrate until the display element is covered, wherein the at least one inorganic layer and the at least one organic layer form a first package layer and a third package layer, the first package layer is formed in the hollow portion, and the third package surrounds and covers the display element.
